(19) United States
(12) Patent Application Publication
(10) Pub. No.: US 2023/0110217 A1
(43) Pub. Date: Apr. 13, 2023

(54) RADIO FREQUENCY RECEPTION COIL NETWORKS FOR SINGLE-SIDED MAGNETIC RESONANCE IMAGING

(71) Applicant: PROMAXO, INC., Oakland, CA (US)

(72) Inventors: Aleksandar NACEV, San Francisco, CA (US); Hongli DONG, Newark, CA (US); Sabareish ATHIVEERA RAMA PANDIAN, San Francisco, CA (US); Dinesh KUMAR, Roseville, CA (US); John NOLTE, Citrus Heights, CA (US)

(73) Assignee: PROMAXO, INC., Oakland, CA (US)

(21) Appl. No.: 17/904,501

(22) PCT Filed: Feb. 19, 2021
(86) PCT No.: PCT/US2021/018834

§ 371 Date: Aug. 18, 2022

Related U.S. Application Data
(60) Provisional application No. 62/979,332, filed on Feb. 20, 2020.

(51) Int. Cl. G01R 33/383; G01R 33/36; G01R 33/385; G01R 33/34

(52) U.S. Cl. CPC G01R 33/383; G01R 33/3628; G01R 33/385; G01R 33/34007; G01R 33/365

(57) ABSTRACT

Disclosed is a single-sided magnetic imaging apparatus, comprising a permanent magnet, wherein a Z axis is defined through the permanent magnetic into a field of view. The single-sided magnetic imaging apparatus further comprises an electromagnet, a gradient coil set, a radio frequency transmission coil, a radio frequency reception coil, and a power source. The power source is configured to generate an electromagnetic field in the field of view along the Z axis. The electromagnetic field comprises a field gradient in the field of view, wherein a timing of the radio frequency transmission coil is configured to target a location within the field gradient in the field of view.

### CROSS-REFERENCE TO RELATED APPLICATION

This application claims the benefit of priority under 35 U.S.C. § 119(e) to U.S. Provisional Patent Application Ser. No. 62/979,332, titled SYSTEM AND METHOD FOR UTILIZING RADIO FREQUENCY RECEIVE NETWORK FOR SINGLE-SIDED MAGNETIC RESONANCE IMAGING, filed Feb. 20, 2020, the entire disclosure of which is herein incorporated by reference.

### BACKGROUND

Magnetic resonance imaging (MRI) systems have primarily been focused on leveraging an enclosed form factor. This form factor includes surrounding the imaging region with electromagnetic field producing materials and imaging system components. A typical MRI system includes a cylindrical bore magnet where the patient is placed within the tube of the magnet for imaging. Components, such as radio frequency (RF) transmission coil(s) (TX) and reception coil(s) (RX) are then placed on many sides of the patient to effectively surround the patient in order to perform the imaging.

Typically, the RF-TX coils are large and fully surround the field of view (i.e., the imaging region), while the RF-RX coils are small and placed right on the field of view. In various existing MRI systems, the placement of these components and other components, which virtually surround the patient, severely limits the movement of the patient. The positioning of the RF-TX and/or RF-RX coils relative to the patient can cause additional burdens during situating the patient within the imaging region and/or removing the patient from within the imaging region. For example, the RF-RX coils are often placed directly onto the patient before the patient is inserted into the imaging bore of the magnet. These coils can restrain patient motion and, as a result, only certain orientation of the patient and coils relative to the patient can be obtained. In other MRI systems, the patient is placed between two large plates to relieve some physical restrictions on patient placement. Regardless, a need exists to provide modern imaging configurations in next generation MRI systems that further alleviate the aforementioned issues with regards to patient comfort and burdensome positional limitations.

### SUMMARY

In one general aspect, the present disclosure provides a single-sided magnetic imaging apparatus, comprising a permanent magnet, wherein a Z axis is defined through the permanent magnetic into a field of view. The single-sided magnetic imaging apparatus further comprises an electromagnet, a gradient coil set, a radio frequency transmission coil, a radio frequency reception coil, and a power source. The power source is configured to generate an electromagnetic field in the field of view along the Z axis. The electromagnetic field comprises a field gradient in the field of view, wherein a tuning of the radio frequency transmission coil is configured to target a location within the field gradient in the field of view.

In another aspect, the present disclosure provides a method of tuning a single-sided magnetic imaging apparatus comprising a permanent magnet, an electromagnet, a gradient coil set, a radio frequency transmission coil, a radio frequency reception coil and a power source configured to generate an electromagnetic field in a region of interest. The method of tuning comprises accessing a field gradient in the electromagnetic field, and adjusting a parameter of the radio frequency reception coil to target an imaging location within the field gradient.

### BRIEF DESCRIPTION OF THE DRAWINGS

The novel features of the various aspects are set forth with particularity in the appended claims. The described aspects, however, both as to organization and methods of operation, may be best understood by reference to the following description, taken in conjunction with the accompanying drawings.

FIG. 1 is a schematic illustration of a magnetic resonance imaging system, according to various aspects of the present disclosure.

FIG. 2 is an exploded, perspective view of the magnetic resonance imaging system shown in FIG. 1, according to various aspects of the present disclosure.

FIG. 3 is an elevation view of the magnetic resonance imaging system shown in FIG. 1, according to various aspects of the present disclosure.

FIG. 4 is an elevation view of the magnetic resonance imaging system shown in FIG. 1, according to various aspects of the present disclosure.

FIG. 5 illustrates exemplary positioning of a patient for imaging by a magnetic resonance imaging system for certain surgical procedures and interventions, according to various aspects of the present disclosure.

FIG. 6 is an example schematic of an RF-RX array including individual coil elements and a variable magnetic field, in accordance with various aspects of the present disclosure.

FIG. 7 is an example illustration of a loop coil along with example variables for a loop coil magnetic field, according to various aspects of the present disclosure.

FIG. 8 is an example X-Y chart illustrating the magnetic field as a function of radius of a loop coil, according to various aspects of the present disclosure.

FIG. 9 is a cross-sectional illustration of a portion of the human body including an area around the prostate, according to various aspects of the present disclosure.

FIG. 10 is an elevation view of an RF-RX array in a housing, depicting the housing as a transparent component for illustrative purposes in order to expose the individual coil elements therein, according to various aspects of the present disclosure.

FIG. 11 is another elevation view of the RF-RX array of FIG. 10, according to various aspects of the present disclosure.

FIG. 12 is a perspective view of the RF-RX array of FIG. 10, according to various aspects of the present disclosure.

The accompanying drawings are not intended to be drawn to scale. Corresponding reference characters indicate corresponding parts throughout the several views. For purposes of clarity, not every component may be labeled in every drawing. The exemplifications set out herein illustrate certain embodiments of the invention, in one form, and such exemplifications are not to be construed as limiting the scope of the invention in any manner.

### DETAILED DESCRIPTION

The following international patent applications are incorporated by reference herein in their respective entireties:
International Application No. PCT/US2020/018352, titled SYSTEMS AND METHODS FOR ULTRALOW FIELD RELAXATION DISPERSION, filed Feb. 14, 2020, now International Publication No. WO2020/168233;
International Application No. PCT/US2020/019530, titled SYSTEMS AND METHODS FOR PERFORMING MAGNETIC RESONANCE IMAGING, filed Feb. 24, 2020, now International Publication No. WO2020/172673;
International Application No. PCT/US2020/019524, titled PSEUDO-BIRDCAGE COIL WITH VARIABLE TUNING AND APPLICATIONS THEREOF, filed Feb. 24, 2020, now International Publication No. WO2020/172672;
International Application No. PCT/US2020/024776, titled SINGLE-SIDED FAST MRI GRADIENT FIELD COILS AND APPLICATIONS THEREOF, filed Mar. 25, 2020, now International Publication No. WO2020/198395;
International Application No. PCT/US2020/024778, titled SYSTEMS AND METHODS FOR VOLUMETRIC ACQUISITION IN A SINGLE-SIDED MRI SYSTEM, filed Mar. 25, 2020, now International Publication No. WO2020/198396;
International Application No. PCT/US2020/039667, title SYSTEMS AND METHODS FOR IMAGE RECONSTRUCTIONS IN MAGNETIC RESONANCE IMAGING, filed Jun. 25, 2020, now International Publication No. WO2020/264194; and
International Application No. PCT/US2021/014628, titled MRI-GUIDED ROBOTIC SYSTEMS AND METHODS FOR BIOPSY, filed Jan. 22, 2021.

U.S. patent application Ser. No. 16/003,585, titled UNILATERAL MAGNETIC RESONANCE IMAGING SYSTEM WITH APERTURE FOR INTERVENTIONS AND METHODOLOGIES FOR OPERATING SAME, filed Jun. 8, 2018, is incorporated by reference herein in its entirety.

The following U.S. provisional patent applications are incorporated by reference herein in their respective entireties:
U.S. Provisional Patent Application No. 62/987,286, titled SYSTEMS AND METHODS FOR ADAPTING DRIVEN EQUILIBRIUM FOURIER TRANSFORM FOR SINGLE-SIDED MRI filed Mar. 9, 2020; and
U.S. Provisional Patent Application No. 62/987,292, titled SYSTEMS AND METHODS FOR LIMITING K-SPACE TRUNCATION IN A SINGLE-SIDED MRI SCANNER, filed Mar. 9, 2020.

Before explaining various aspects of an MRI system and methods in detail, it should be noted that the illustrative examples are not limited in application or use to the details of construction and arrangement of parts illustrated in the accompanying drawings and description. The illustrative examples may be implemented or incorporated in other aspects, variations, and modifications, and may be practiced or carried out in various ways. Further, unless otherwise indicated, the terms and expressions employed herein have been chosen for the purpose of describing the illustrative examples for the convenience of the reader and are not for the purpose of limitation thereof. Also, it will be appreciated that one or more of the following-described aspects, expressions of aspects, and/or examples, can be combined with any one or more of the other following-described aspects, expressions of aspects, and/or examples.

Typical MRI systems create a uniform field within the imaging region. This uniform field then generates a narrow band of magnetic resonance frequencies that can then be captured by a receive coil (RF-RX), amplified, and digitized by a spectrometer. Since frequencies are within a narrow well-defined bandwidth, hardware architecture is focused on creating a statically tuned RF-RX coil with an optimal coil quality factor. Many variations in coil architectures have been created that explore large single volume coils, coil arrays, parallelized coil arrays, or body specific coil arrays. However, these structures are predicated on imaging a specific frequency close to the interest at high field strengths and are as small as possible to fit within the magnetic bore or tube of an enclosed MRI apparatus.

In accordance with various aspects, an MRI system is provided that can include a unique imaging region that can be offset from the face of a magnet. Such offset and single-sided MRI systems are less restrictive as compared to traditional scanners. In addition, this form factor can have a built-in magnetic field gradient that creates a range of field values over the region of interest. Moreover, this system can operate at a lower magnetic field strength as compared to typical MRI systems allowing for a relaxation on the RX coil design constraints and/or allowing for additional mechanisms, like robotics, for example, to be used with the MRI. Exemplary MRI-guided robotic systems are further described in International Application No. PCT/US2021/01 region of4628, titled MRI-GUIDED ROBOTIC SYSTEMS AND METHODS FOR BIOPSY, filed Jan. 22, 2021, for example.

The unique architecture of the main magnetic field of the MRI system, in accordance with various aspects of the present disclosure, can create a different set of optimization constraints. Because the imaging volume now extends over a broader range of magnetic resonance frequencies, the hardware can be configured to be sensitive to and capture the specific frequencies that are generated across the field of view. This frequency spread is usually much larger than a single receive coil tuned to a single frequency can be sensitive to. In addition, because the field strength can be much lower than traditional systems, and because signal intensity can be proportional to the field strength, it is generally considered to be beneficial to maximize the Signal-to-Noise Ratio (SNR) of the receive coil network. Methods are therefore provided, in accordance with various aspects, to acquire the full range of frequencies that are generated within the field of view without a loss of sensitivity.

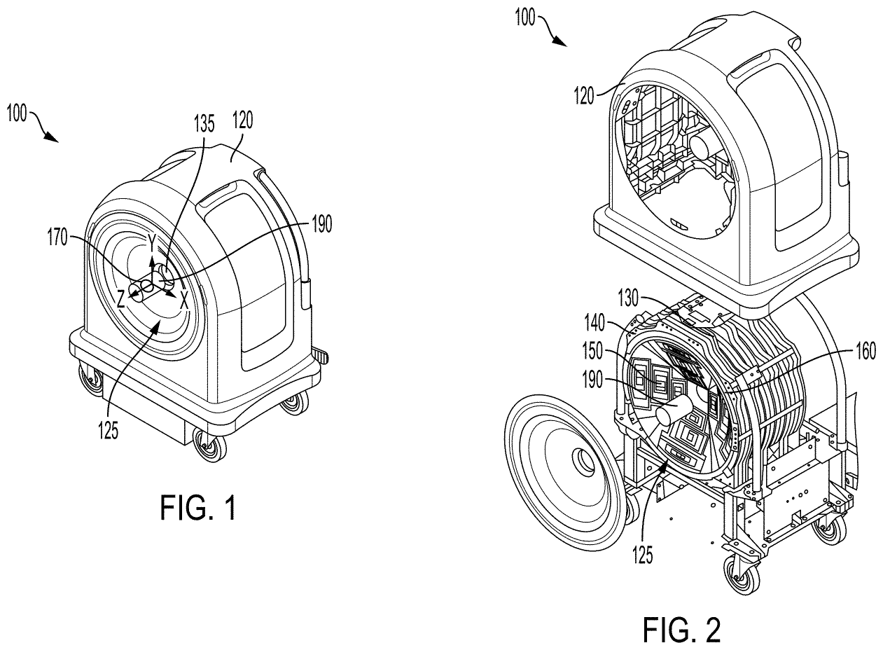

FIGS. 1-5 depict a magnetic resonance imaging system 100. As shown in FIGS. 1 and 2, the magnetic resonance imaging system 100 includes a housing 120. The housing 120 includes a front surface 125. In accordance with various aspects, the front surface 125 can be a concave and/or recessed front surface.

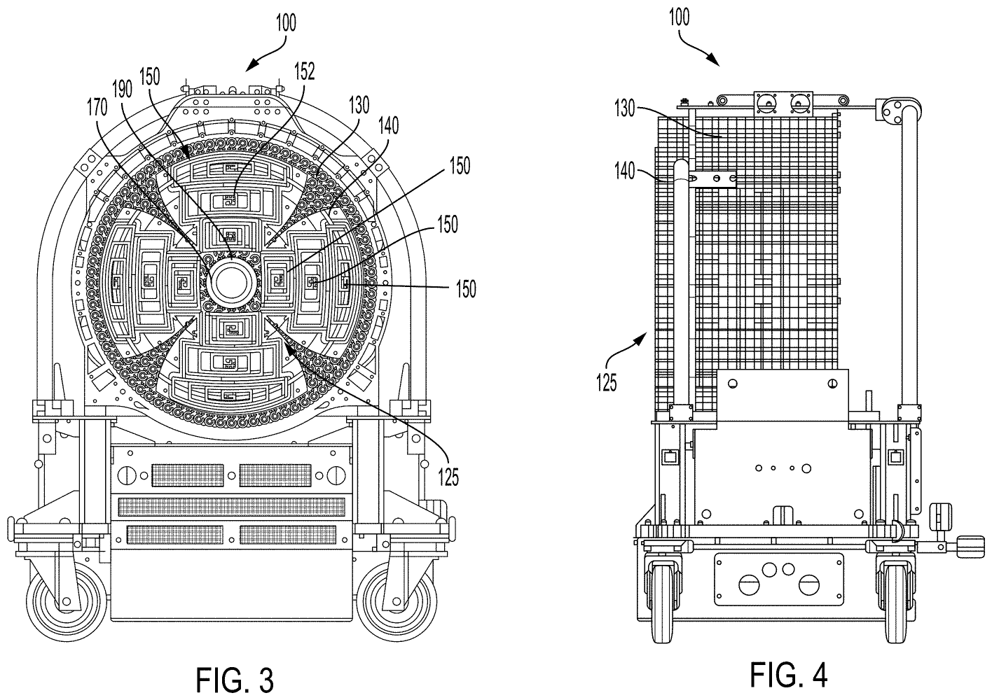

As shown in FIGS. 1 and 2, the housing 120 includes a permanent magnet 130, a radio frequency transmit coil 140, a gradient coil set 150, an electromagnet 160, and a radio frequency receive coil 170. As shown in FIGS. 3 and 4, the permanent magnet 130 can include a plurality of magnets disposed in an array configuration. The plurality of magnets forming the permanent magnet 130 are configured to cover an entire surface as shown in the front elevation view of FIG. 3 and illustrated as bars in a horizontal direction as shown in the side election view of FIG. 4. Referring primarily to FIG. 1, the main permanent magnet array can include at least one access aperture or bore 135, which can provide access to the patient through the housing 120 from the opposite side of the housing 120. In other aspects of the present disclosure, the permanent magnetic array may be bore-less and define a uninterrupted arrangement of permanent magnets without a bore defined therethrough.

In accordance with various aspects of the present disclosure, the permanent magnet 130 provides a static magnetic field in a region of interest 190. In accordance with various embodiments, the permanent magnet 130 can include a plurality of cylindrical permanent magnets in parallel configuration as shown in FIGS. 3 and 4. In accordance with various embodiments, the permanent magnet 130 can include any suitable magnetic materials, including but not limited to rare-earth based magnetic materials, such as for example, Nd-based magnetic materials, and the like..

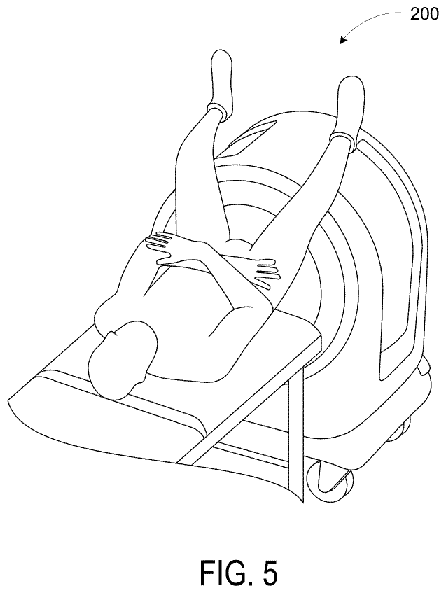

In accordance with various aspects, using the magnetic resonance imaging system 100 illustrated in FIGS. 1-4, a patient can be positioned in any number of different positions depending on the type of anatomical scan. As an example, as illustrated in FIG. 5, when the pelvis is scanned with the magnetic resonance imaging system 100, the patient can be laid on a surface in a lithotomy position. As illustrated in FIG. 5, for the pelvic scan, a patient can be positioned to have their back resting on the table and legs raised up to be resting against the top of the system 100. The pelvic region can be positioned directly in front of the bore 135.

In accordance with various aspects, several methods are provided that can enable imaging within the MRI system 100. These methods can include combining one or more of a variable tuned RF-RX coil, a RF-RX coil array with elements tuned to frequencies that are dependent upon the spatial inhomogeneity of the magnetic field, a ultralow-noise pre-amplifier design, and an RF-RX array with multiple receive coils designed to optimize the signal from a defined and limited field of view for a specific body part. These methods can be combined in any combination as needed.

In various aspects of the present disclosure, a variable tuned RF-RX coil can by incorporated in the MRI system 100. For example, the radio frequency receive coil 170 can include a variable turned RF-RX coil. A variable turned RF-RX coils can comprise one or more electronic components for tuning the electromagnetic receive field. In various implementations, the one or more electronic components can include at least one of a varactor, a PIN diode, a capacitor, an inductor, a MEMS switch, a solid state relay, or a mechanical relay. In various implementations, the one or more electronic components used for tuning can include at least one of dielectrics, capacitors, inductors, conductive metals, metamaterials, or magnetic metals. In various implementations, tuning the electromagnetic receive field can be achieved with different methods, such as a voltage adjustment method which involves changing the voltage to activate a component or a physical relocation method which involves changing physical locations of the one or more electronic components to thereby adjust capacitive or inductive characteristics.

The voltage adjustment method involves using a passive dev ice with switching capabilities. The most common device used for this is a PIN diode. By applying a forward voltage, the PIN diode is biased forward, which means the PIN diode is turned on thereby allowing the passage of current to the device to which it is connected. This method can be useful to selectively turn on coils by sending a forward voltage to the coil which should be used. However, a disadvantage of this method is that the PIN diodes can be quite expensive compared to the cost of the actual receive coil and can be prone to breaking during transmission due to voltage spikes from the TX coil. The physical relocation method requires moving the coils physically to change their inductive and capacitive characteristics. Since this process involves physical movement of the coil, it may create additional burdens to the patient during a scan in certain instances. Both methods will adjust the inherent resonant frequency or coil bandwidth.

In various implementations, the coil is cryogenically cooled to reduce resistance and improve efficiency.

In various aspects of the present disclosure, the MRI system 100 can include an RF-RX array including individual coil elements that are tuned to a variety of frequencies. The appropriate frequency can be chosen, for example, to match the frequency of the magnetic field located at the specific spatial location where the specific coil is located.

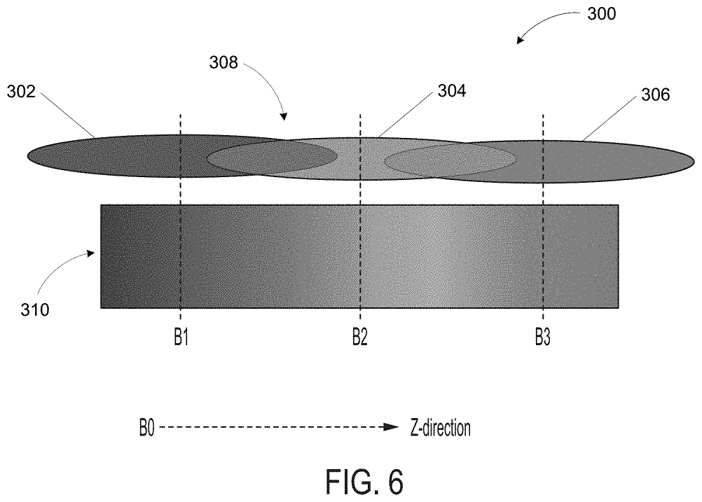

Referring now to a schematic 300 of FIG. 6, a RF-RX array 308 and a magnetic field 310 are shown. The magnetic field 310 can vary as a function of space, and the field and frequency of the coil(s) 302, 304, 306 in the RF-RX array 308 can be adjusted to approximately match the spatial location. Here the coils 302, 304, 306 can be designed to image the field locations B1, B2, and B3, which are physically separated along a single axis B0 in the Z direction. In FIG. 6 the coils 302, 304, 306 overlap adjacent coil(s), as shown by the ovals crossing each other.

The RF-RX array 308 of FIG. 6 can be incorporated into the magnetic imaging system 100. For example, the radio frequency receive coil 170 can further include a tunable RF-RX array along a Z-axis.

For a low magnetic field system, such as the system 100, for example, a low-noise preamplifier can be designed and configured to leverage the low signal environment of the MRI system. This low-noise amplifier can be configured to utilize components that do not generate significant electronic and voltage noise at the desired frequencies (for example, <4 MHz and >2 MHz). When there is an input signal to the preamplifier, the signal and noise get amplified by the same amount (gain) of the preamplifier. To obtain useful low noise amplification, the signal amplitude should be high while maintaining low noise. To keep the noise to a minimum, the SNR of the preamplifier should be high. One method of achieving good SNR, while keeping the noise levels low is to add operational amplifiers (“opamps”) in parallel. Typical junction field effect transistor designs (J-FET) generally do not have the appropriate noise characteristics at this frequency and can create high frequency instabilities at the GHz range that can bleed into, although several decades of dB lower, the measured frequency range. Since the gain of the system can preferably be, for example, >80 dB overall, any small instabilities or intrinsic electrical noise can be amplified and degrade signal integrity.

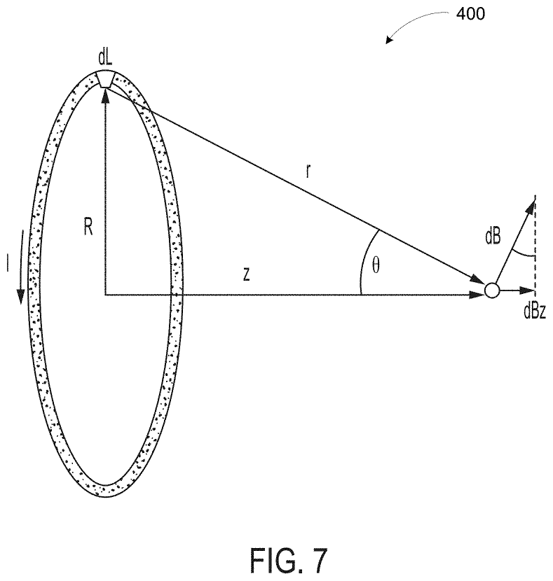

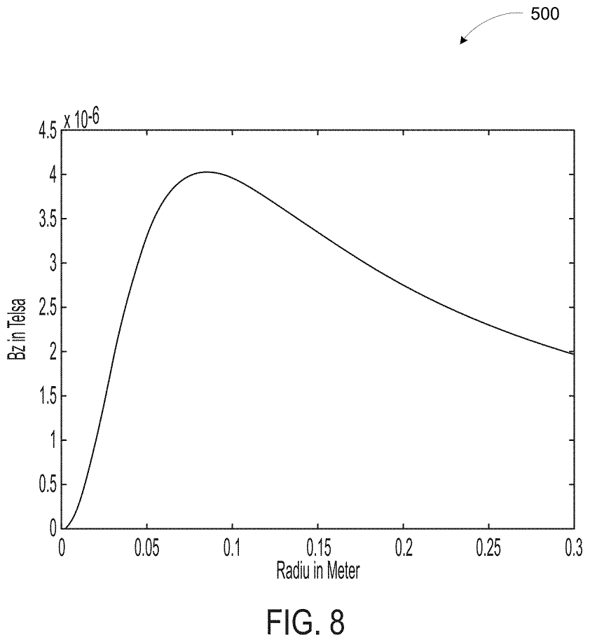

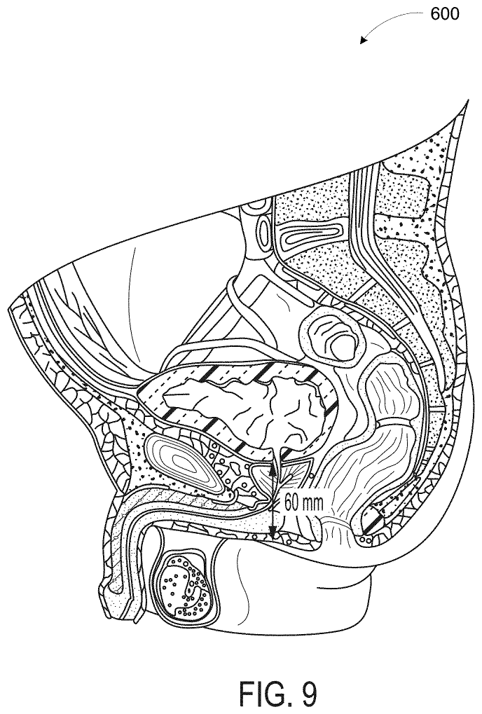

In various aspects of the present disclosure, RF-RX coils can be designed to image specific limited field of views based upon the target anatomy. For example, referring to a diagram 600 in FIG. 9, the prostate is about 60 millimeters deep within the human body. To design a RF-RX coil for prostate imaging, the coil should be configured to enable imaging 60 mm deep inside human body. Referring to the variables and coil schematic 500 in FIG. 7, and according to Biot-Savart law, the magnetic field of a loop coil can be calculated by the following equation:

$$Bz = \frac{{μ}_{0}}{4 π} * \frac{2 π * {R}^{2} - I}{{( {z}^{2} + {R}^{2} )}^{\frac{3}{2}}}$$

where μ0=4π*10⁻⁷ H/m is the vacuum permeability, R is the radius of the loop coil, z is distance along the center line of the coil from its center, and I is the current on the coil. Assuming I=1 Ampere, with the goal of locating a figure of magnetic field (Bz) at z=60 mm, the maximum position is when R is 85-mm according to a chart 500 shown in FIG. 8.

A low-impedance preamplifier design with an input impedance below 5 Ohms can be used in series with the matching network of a coil in a receive coil array to provide active decoupling from adjacent coils in the same array. This technique does not rely upon geometric decoupling to cancel out mutual inductance between coils, and allows individual coils in the array to be decoupled from each other using the low noise preamplifier itself. Each coil in a receive coil array has an inductive and capacitive matching network that is used to match the resistance of the coil to 50 Ohms for maximum power transfer. When a low impedance preamplifier is connected to the matching network of a coil, the low impedance acts as a short, thereby making the impedance seen into the coil infinite and trapping any coil currents.

Based upon the geometrical constraints of the body, a loop coil can be set up at the space between the human legs upon the torso. As such, it is extremely difficult, if not impossible, to fit a 170-mm diameter coil at that location. According to FIG. 8, the Bz field value is increases in relation to the radius of the loop when R is less than 85 mm. As such, it is advantageous that the coil be as large as it can be. For example, the largest loop coil that can be placed between the human legs is about 10-cm in diameter.

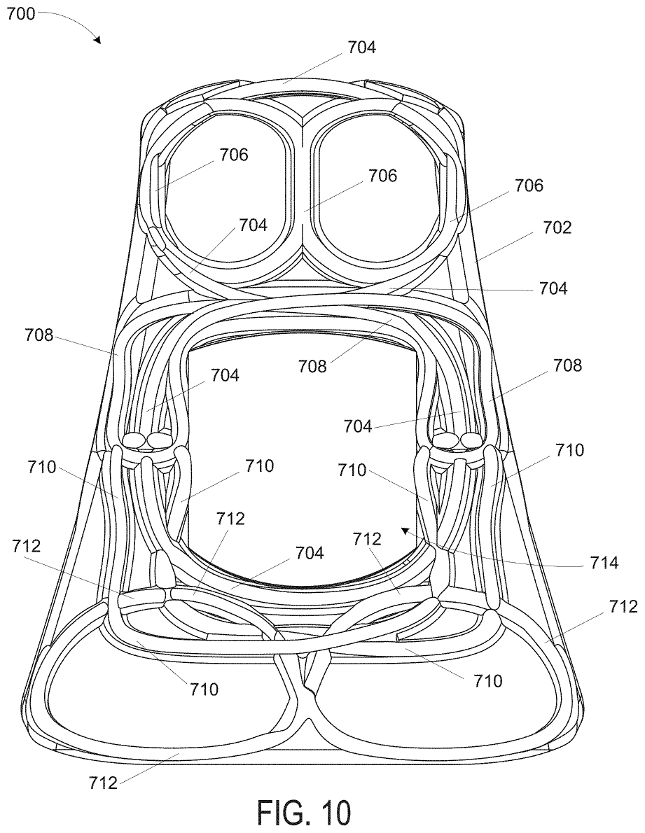

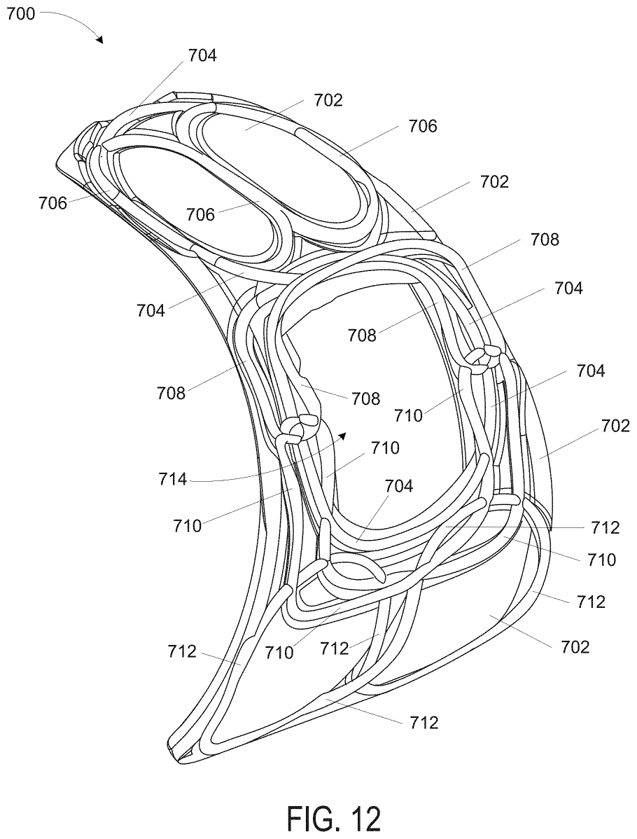

As the site of the coil can be generally limited by a space, e.g. between a person's legs, the magnetic field of a 10-cm diameter coil is generally not capable of reaching to the depth of the prostate. Therefore, a single coil may not be enough, for example, for prostate imaging. Thus, in this case, multiple coils could prove beneficial in getting signals from different directions. In various aspects of the MRI system, the magnetic field is provided in the z-direction and RF coils are sensitive to x- and y-direction. In this example case, a loop coil in x-y plane would not collect RF signal from a human since it is sensitive to z-direction, while a butterfly coil can be used in this case. Then based on the location and orientation, the RF coil could be a loop coil or a butterfly coil. In addition, a coil can be placed in under the body and there is no limitation for its size. FIGS. 10-12, which are further described herein, depict an RF array 700 including a combination of different types of coils, for example.

As for the needs of multiple RX coils, in various aspects of the present disclosure, decoupling between them can prove beneficial for various aspects of an MRI system RX coil array. In those cases, each coil can be decoupled with the other coils, and the decoupling techniques can include, for example, 1) geometry decoupling, 2) capacitive/inductive decoupling, and 3) low-/high impedance pre-amplifier coupling.

Geometric decoupling can be the simplest decoupling technique as it does not involve any active or passive circuit elements to achieve the required decoupling. Each coil in a receive coil array is a current carrying wire, meaning each coil has its own self inductance and mutual inductance. When a receive coil is excited with voltage, it creates a magnetic field which is effectively “seen” by any coils adjacent to it, which in turn creates noise. To reduce this effect, coils are geometrically arranged in such a way that the mutual inductance between them is the lowest. A disadvantage to this method is that the coils are constrained by geometry and any additional motion or manipulation of the geometry of the coils (e.g. from bending) will change the coil inductance and the mutual inductance leading to a change in the decoupling.

The MRI system, in accordance with various aspects, can have a variant magnetic field from the magnet, and its strength can vary linearly along the z direction. The RX coils can be located in different positions in z-direction, and each coil can be tuned to different frequencies, which can depend on the location of the coils in the system.

Based upon the simplicity of single coil loops, these coils can be constructed from simple conductive traces that can be pre-tuned to a desired frequency and printed, for example, on a disposable substrate. This cheaply fabricated technology can allow a clinician to place the RX coil (or coil array) upon the body at the region of interest fora given procedure and dispose of the coil afterwards. These coils can be constructed from 3D printing copper, silver, or other electrically conductive inks onto a plastic or woven material, for example. Alternatively, electrically conductive wires can be woven into a fabric to create a coil robust to deformation. For example, the RX coils can be surface coils, which can be worn or taped to a patient's body. For certain body parts, e.g. an ankle or a wrist, the surface coil might be a single loop, figure 8 design, or butterfly coil wrapped around the region of interest. For regions that require significant penetration depth, e.g. the torso or knee, the coil might consist of a Helmholtz coil pair. As with receive coils of other MRI systems, the coil is optimally sensitive to a plane that is orthogonal to the main magnetic field, B0 of FIG. 6, axis.

In some instances, the coils might be inductively coupled to another loop that is electrically connected to the receive preamplifier. This design would allow for easier and unobstructed access of the receive coils. In receive coils from other MRI systems, the preamplifier might be on the coil to reduce any signal loss due to cable loss, insertion loss, etc. This also means that the preamplifier will be present close to or on the patient, thereby being an electrical hazard. By moving the receive preamplifiers away from the receive coil, the patient can have an unobstructed access to the receive coil in various aspects of the present disclosure.

In accordance with various aspects of the present disclosure, the size of coils can be limited by the structure of human body. For example, the coils' size should be positioned and configured to fit in the space between human legs when imaging the prostate.

Referring to FIGS. 10-12, a RF-RX array 700 is shown. The RF-RX array 700 is positioned within a housing or enclosure 702, which houses the different coils that make up the RF-RX array 700. In the example embodiment shown in FIGS. 10-12, the RF-RX array 700 comprises five coils 704, 706, 708, 710, and 712. The coils 704, 706, 708, 710, and 712 are butterfly coils comprising a pair of lobes. The first coil 704 forms a first lobe or loop at an upper portion of the array and a second lobe or loop in a middle portion of the array. The first loop of the first coil 704 surrounds the second coil 706. The second loop of the first coil 704 surrounds a through hole 714 in the enclosure 702. The second coil 706 is located above the through hole 714. The third coil 708 extends around the upper half of the through hole 714. The fourth coil 710 extends around the lower half of the through hole 714. Ends of the loops of the third and fourth coil 708, 710 overlap at a vertical centerline through the through hole 714. The first coil 704 also overlaps/underlaps a portion of the second coil 706, the third coil 708, and the fourth coil 710. The fifth coil 712 is positioned along a lower portion of the enclosure 702 below the through hole 714. All of the coils 704, 708, 710, and 712 overlap each other in areas so that at least a portion of each coil sits on top of a portion of one other coil in order to form an overlapping array.

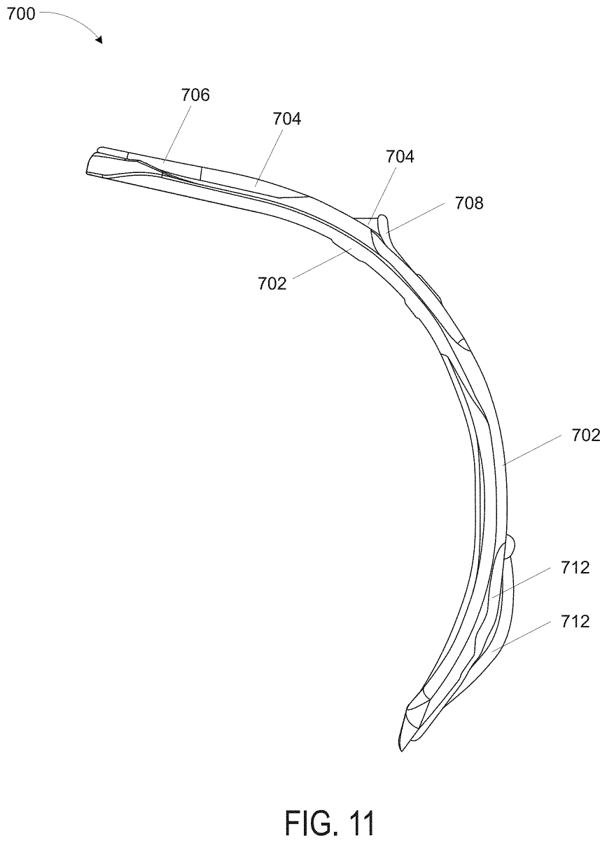

The enclosure 702 also defines a curve, which is best shown in FIG. 11. In other embodiments, the enclosure 702 and coils therein can define a different radius of curvature or multiple different radii of curvature. A different number of coils could be included in alternative RF-RX arrays and/or the coils could comprise different geometries and/or sizes, for example.

### Examples

Various aspects of the subject matter described herein are set out in the following numbered examples.

Example 1—A single-sided magnetic imaging apparatus, comprising a permanent magnet, wherein a Z axis is defined through the permanent magnetic into a field of view. The single-sided magnetic imaging apparatus further comprises an electromagnet, a gradient coil set, a radio frequency transmission coil, a radio frequency reception coil, and a power source. The power source is configured to generate an electromagnetic field in the field of view along the Z axis. The electromagnetic field comprises a field gradient in the field of view, wherein a tuning of the radio frequency transmission coil is configured to target a location within the field gradient in the field of view.

Example 2—The single-sided magnetic imaging apparatus of Example 1, wherein the tuning of the radio frequency transmission coil comprises repositioning the radio frequency transmission coil along the Z axis.

Example 3—The single-sided magnetic imaging apparatus of Examples 1 or 2, wherein the tuning of the radio frequency transmission coil comprises adjusting a current supplied to the radio frequency reception coil.

Example 4—The single-sided magnetic imaging apparatus of Examples 1, 2, or 3, wherein the tuning of the radio frequency transmission coil comprises relocating at least one electronic component selected from a group consisting of a varactor, a pin diode, a capacitator, an inductor, a MEMS switch, a solid state relay, and a mechanical relay.

Example 5—The single-sided magnetic imaging apparatus of Examples 1, 2, 3, or 4, wherein the radio frequency reception coil comprises a coil printed on a disposable substrate.

Example 6—The single-sided magnetic imaging apparatus of Examples 1, 2, 3, 4, or 5, wherein the radio frequency reception coil comprises an array of radio frequency reception coils.

Example 7—The single-sided magnetic imaging apparatus of Example 6, wherein the array of radio frequency reception coils comprise a first coil and a second coil, and wherein the first coil and the second coil are decoupled.

Example 8—The single-sided magnetic imaging apparatus of Examples 6 or 7, wherein the array of radio frequency reception coils comprise a first coil and a second coil, and wherein the first coil and the second coil are positioned to receive signals from different directions.

Example 9—The single-sided magnetic imaging apparatus of Examples 7 or 8, wherein the first coil and the second coil comprise different geometries.

Example 10—The single-sided magnetic imaging apparatus of Examples 6, 7, 8, or 9, wherein the array of radio frequency reception coils comprise a first coil and a second coil, and wherein the first coil and the second coil are longitudinally-staggered along the Z axis.

Example 11—The single-sided magnetic imaging apparatus of Examples 7, 8, 9, or 10, wherein the first coil and the second coil partially overlap.

Example 12—The single-sided magnetic imaging apparatus of Examples 7, 8, 9, 10, or 11, wherein the first coil and the second coil are tuned to different frequencies.

Example 13—The single-sided magnetic imaging apparatus of Examples 7, 8, 9, 10, 11, or 12, wherein the first coil is tuned to correspond to a first frequency of the field gradient field at the location along the Z axis, and wherein the second coil is tuned to match a second frequency of the field gradient at a second location along the Z axis.

Example 14—The single-sided magnetic imaging apparatus of Examples 1, 2, 3, 4, 5, 6, 7, 8, 9, 10, 11, 12, and 13, further comprising a housing comprising a concave outer surface, wherein the permanent magnet is positioned within the housing, and wherein the field of view is external to the housing and offset from the concave outer surface.

Example 15—A method of tuning a single-sided magnetic imaging apparatus comprising a permanent magnet, an electromagnet, a gradient coil set, a radio frequency transmission coil, a radio frequency reception coil and a power source configured to generate an electromagnetic field in a region of interest. The method of tuning comprises accessing a field gradient in the electromagnetic field, and adjusting a parameter of the radio frequency reception coil to target an imaging location within the field gradient.

Example 16—The method of Example 15, wherein adjusting a parameter of the radio frequency reception coil to target an imaging location within the field gradient comprises repositioning the radio frequency transmission coil.

Example 17—The method of Examples 15 or 16, wherein adjusting a parameter of the radio frequency reception coil to target an imaging location within the field gradient comprises adjusting a current supplied to the radio frequency reception coil.

Example 18—The method of Examples 15, 16, or 17, wherein adjusting a parameter of the radio frequency reception coil to target an imaging location within the field gradient comprises relocating at least one electronic component selected from a group consisting of a varactor, a pin diode, a capacitator, an inductor, a MEMS switch, a solid state relay, and a mechanical relay.

Example 19—The method of Examples 15, 16, 17, or 18, wherein adjusting a parameter of the radio frequency reception coil to target an imaging location within the field gradient comprises tuning the radio frequency reception coil to a predefined frequency based on the target anatomy.

Example 20—The method of Examples 15, 16, 17, 18, or 19, wherein the magnetic imaging apparatus comprises an array of radio frequency reception coils, and wherein the method of turning further comprises adjusting the coils in the array of radio frequency coils to different frequencies.

While several forms have been illustrated and described, it is not the intention of Applicant to restrict or limit the scope of the appended claims to such detail. Numerous modifications, variations, changes, substitutions, combinations, and equivalents to those forms may be implemented and will occur to those skilled in the art without departing from the scope of the present disclosure. Moreover, the structure of each element associated with the described forms can be alternatively described as a means for providing the function performed by the element.

Also, where materials are disclosed for certain components, other materials may be used. It is therefore to be understood that the foregoing description and the appended claims are intended to cover all such modifications, combinations, and variations as falling within the scope of the disclosed forms. The appended claims are intended to coverall such modifications, variations, changes, substitutions, modifications, and equivalents.

The foregoing detailed description has set forth various forms of the devices and/or processes via the use of block diagrams, flowcharts, and/or examples. Insofar as such block diagrams, flowcharts, and/or examples contain one or more functions and/or operations, it will be understood by those within the at that each function and/or operation within such block diagrams, flowcharts, and/or examples can be implemented, individually and/or collectively, by a wide range of hardware, software, firmware, or virtually any combination thereof. Those skilled in the art will recognize that some aspects of the forms disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as one or more program products in a variety of forms, and that an illustrative form of the subject matter described herein applies regardless of the particular type of signal bearing medium used to actually carry out the distribution.

Instructions used to program logic to perform various disclosed aspects can be stored within a memory in the system, such as dynamic random access memory (DRAM), cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, compact disc, read-only memory (CD-ROMs), and magneto-optical disks, read-only memory (ROMs), random access memory (RAM), erasable programmable read-only memory (EPROM), electrically erasable programmable read-only memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the non-transitory computer-readable medium includes any type of tangible machine-readable medium suitable for storing or transmitting electronic instructions or information in a form readable by a machine (e.g., a computer).

As used in any aspect herein, the term “control circuit” may refer to, for example, hardwired circuitry, programmable circuitry (e.g., a computer processor including one or more individual instruction processing cores, processing unit, processor, microcontroller, microcontroller unit, controller, digital signal processor (DSP), programmable logic device (PLD), programmable logic array (PLA), or field programmable gate array (FPGA)), state machine circuitry, firmware that stores instructions executed by programmable circuitry, and any combination thereof. The control circuit may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Accordingly, as used herein “control circuit” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

As used in any aspect herein, the term “logic” may refer to an app, software, firmware and/or circuitry configured to perform any of the aforementioned operations. Software may be embodied as a software package, code, instructions, instruction sets and/or data recorded on non-transitory computer readable storage medium.

Firmware may be embodied as code, instructions or instruction sets and/or data that are hard-coded (e.g., nonvolatile) in memory devices.

As used in any aspect herein, the terms “component,” “system,” “module” and the like can refer to a computer-related entity, either hardware, a combination of hardware and software, software, or software in execution.

As used in any aspect herein, an “algorithm” refers to a self-consistent sequence of steps leading to a desired result, where a “step” refers to a manipulation of physical quantities and/or logic states which may, though need not necessarily, take the form of electrical or magnetic signals capable of being stored, transferred, combined, compared, and otherwise manipulated. It is common usage to refer to these signals as bits, values, elements, symbols, characters, terms, numbers, or the like. These and similar terms may be associated with the appropriate physical quantities and are merely convenient labels applied to these quantities and/or states.

A network may include a packet switched network. The communication devices may be capable of communicating with each other using a selected packet switched network communications protocol. One example communications protocol may include an Ethernet communications protocol which may be capable permitting communication using a Transmission Control Protocol/Internet Protocol (TCP/IP). The Ethernet protocol may comply or be compatible with the Ethernet standard published by the Institute of Electrical and Electronics Engineers (IEEE) titled “IEEE 802.3 Standard”, published in December, 2008 and/or later versions of this standard. Alternatively or additionally, the communication devices may be capable of communicating with each other using an X.25 communications protocol. The X.25 communications protocol may comply or be compatible with a standard promulgated by the International Telecommunication Union-Telecommunication Standardization Sector (ITU-T). Alternatively or additionally, the communication devices may be capable of communicating with each other using a frame relay communications protocol. The frame relay communications protocol may comply or be compatible with a standard promulgated by Consultative Committee for International Telegraph and Telephone (CCITT) and/or the American National Standards Institute (ANSI). Alternatively or additionally, the transceivers may be capable of communicating with each other using an Asynchronous Transfer Mode (ATM) communications protocol. The ATM communications protocol may comply or be compatible with an ATM standard published by the ATM Forum titled “ATM-MPLS Network Interworking 2.0” published August 2001, and/or later versions of this standard. Of course, different and/or after-developed connection-oriented network communication protocols are equally contemplated herein.

Unless specifically stated otherwise as apparent from the foregoing disclosure, it is appreciated that, throughout the foregoing disclosure, discussions using terms such as “processing,” “computing,” “calculating,” “determining,” “displaying.” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

One or more components may be referred to herein as “configured to,” “configurable to,” “operable/operative to,” “adapted/adaptable,” “able to.” “conformable/conformed to,” etc. Those skilled in the art will recognize that “configured to” can generally encompass active-state components and/or inactive-state components and/or standby-state components, unless context requires otherwise.

The terms “proximal” and “distal” are used herein with reference to a clinician manipulating the handle portion, or housing, of a surgical instrument. The term “proximal” refers to the portion closest to the clinician and/or to the robotic arm and the term “distal” refers to the portion located away from the clinician and/or from the robotic arm. It will be further appreciated that, for convenience and clarity, spatial terms such as “vertical”, “horizontal”, “up” and “down” may be used herein with respect to the drawings. However, robotic surgical tools are used in many orientations and positions, and these terms are not intended to be limiting and/or absolute.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone. B alone. C alone. A and B together. A and C together. B and C together, and/or A. B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein nay generally be performed in any order. Also, although various operational flow diagrams are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect.” “in an exemplification,” and “in one exemplification” in various places throughout the specification are not necessarily all referring to the same aspect. Furthermore, the particular features, structures or characteristics may be combined in any suitable manner in one or more aspects.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

In summary, numerous benefits have been described which result from employing the concepts described herein. The foregoing description of the one or more forms has been presented for purposes of illustration and description. It is not intended to be exhaustive or limiting to the precise form disclosed. Modifications or variations are possible in light of the above teachings. The one or more forms were chosen and described in order to illustrate principles and practical application to thereby enable one of ordinary skill in the art to utilize the various forms and with various modifications as are suited to the particular use contemplated. It is intended that the claims submitted herewith define the overall scope.

What is claimed is:

1. A single-sided magnetic imaging apparatus, comprising:
a permanent magnet, wherein a Z axis is defined through the permanent magnetic into a field of view;
an electromagnet;
a gradient coil set;
a radio frequency transmission coil;
a radio frequency reception coil; and
a power source, wherein the power source is configured to generate an electromagnetic field in the field of view along the Z axis, wherein the electromagnetic field comprises a field gradient in the field of view, and wherein a tuning of the radio frequency transmission coil is configured to target a location within the field gradient in the field of view.

2. The single-sided magnetic imaging apparatus of claim 1, wherein the tuning of the radio frequency transmission coil comprises repositioning the radio frequency transmission coil along the Z axis.

3. The single-sided magnetic imaging apparatus of claim 1, wherein the tuning of the radio frequency transmission coil comprises adjusting a current supplied to the radio frequency reception coil.

4. The single-sided magnetic imaging apparatus of claim 1, wherein the tuning of the radio frequency transmission coil comprises relocating at least one electronic component selected from a group consisting of a varactor, a pin diode, a capacitator, an inductor, a MEMS switch, a solid state relay, and a mechanical relay.

5. The single-sided magnetic imaging apparatus of claim 1, wherein the radio frequency reception coil comprises a coil printed on a disposable substrate.

6. The single-sided magnetic imaging apparatus of claim 1, wherein the radio frequency reception coil comprises an array of radio frequency reception coils.

7. The single-sided magnetic imaging apparatus of claim 6, wherein the array of radio frequency reception coils comprise a first coil and a second coil, and wherein the first coil and the second coil are decoupled.

8. The single-sided magnetic imaging apparatus of claim 6, wherein the army of radio frequency reception coils comprise a first coil and a second coil, and wherein the first coil and the second coil are positioned to receive signals from different directions.

9. The single-sided magnetic imaging apparatus of claim 8, wherein the first coil and the second coil comprise different geometries.

10. The single-sided magnetic imaging apparatus of claim 6, wherein the array of radio frequency reception coils comprise a first coil and a second coil, and wherein the first coil and the second coil are longitudinally-staggered along the Z axis.

11. The single-sided magnetic imaging apparatus of claim 10, wherein the first coil and the second coil partially overlap.

12. The single-sided magnetic imaging apparatus of claim 10, wherein the first coil and the second coil are tuned to different frequencies.

13. The single-sided magnetic imaging apparatus of claim 10, wherein the first coil is tuned to correspond to a first frequency of the field gradient field at the location along the Z axis, and wherein the second coil is tuned to match a second frequency of the field gradient at a second location along the Z axis.

14. The single-sided magnetic imaging apparatus of claim 1, further comprising a housing comprising a concave outer surface, wherein the permanent magnet is positioned within the housing, and wherein the field of view is external to the housing and offset from the concave outer surface.

15. A method of tuning a single-sided magnetic imaging apparatus comprising a permanent magnet, an electromagnet, a gradient coil set, a radio frequency transmission coil, a radio frequency reception coil and a power source configured to generate an electromagnetic field in a region of interest, the method of tuning comprising:
accessing a field gradient in the electromagnetic field; and
adjusting a parameter of the radio frequency reception coil to target an imaging location within the field gradient.

16. The method of claim 15, wherein adjusting a parameter of the radio frequency reception coil to target an imaging location within the field gradient comprises repositioning the radio frequency transmission coil.

17. The method of claim 15, wherein adjusting a parameter of the radio frequency reception coil to target an imaging location within the field gradient comprises adjusting a current supplied to the radio frequency reception coil.

18. The method of claim 15, wherein adjusting a parameter of the radio frequency reception coil to target an imaging location within the field gradient comprises relocating at least one electronic component selected from a group consisting of a varactor, a pin diode, a capacitator, an inductor, a MEMS switch, a solid state relay, and a mechanical relay.

19. The method of claim 15, wherein adjusting a parameter of the radio frequency reception coil to target an imaging location within the field gradient comprises tuning the radio frequency reception coil to a predefined frequency based on the target anatomy.

20. The method of claim 15, wherein the magnetic imaging apparatus comprises an army of radio frequency reception coils, and wherein the method of turning further comprises adjusting the coils in the array of radio frequency coils to different frequencies.
